(19) United States
(12) Patent Application Publication
(10) Pub. No.: US 2018/0331525 A1
(43) Pub. Date: Nov. 15, 2018

(54) ELECTRICAL CONNECTION BOX

(71) Applicant: Yazaki Corporation, Tokyo (JP)

(72) Inventors: Toshiaki Fukuhara, Shizuoka (JP); Toshitaka Iwasaki, Shizuoka (JP); Satoshi Hishikura, Shizuoka (JP); Keisuke Kimura, Shizuoka (JP); Hiroki Kayamori, Shizuoka (JP)

(21) Appl. No.: 15/970,667

(22) Filed: May 3, 2018

(30) Foreign Application Priority Data
May 9, 2017 (JP) 2017-093161

(51) Int. Cl. H02G 3/16; H05K 5/02; G01R 19/00; G01R 15/20

(52) U.S. Cl. CPC H02G 3/16; H05K 5/02; G01R 15/202; G01R 15/207; G01R 19/0092

(57) ABSTRACT

A conductor, a current measurement device that measures current flowing through a current measurement target part of the conductor and outputs an output signal related to the current, and a casing that accommodates the conductor and the current measurement device are included, and the current measurement device includes a magnetic sensor that measures the current, a substrate that outputs the output signal based on an input signal input from the magnetic sensor, and a magnetic shield member in which the magnetic sensors, the substrate, and the current measurement target part are disposed, the magnetic shield member shielding magnetism between inside and outside of the magnetic shield member, and the casing includes a sensor accommodation chamber that accommodates the magnetic sensor and the substrate, a shield insertion port into which the magnetic shield member is inserted, and shield holding chambers holding the magnetic shield member at an accommodation position.

### CROSS-REFERENCE TO RELATED APPLICATION(S)

The present application claims priority to and incorporates by reference the entire contents of Japanese Patent Application No. 2017-093161 filed in Japan on May 9, 2017.

### BACKGROUND OF THE INVENTION

### 1. Field of the Invention

The present invention relates to an electrical connection box.

### 2. Description of the Related Art

In a conventional electrical connection box, a current sensor is provided to measure current flowing through a conductor such as a bus bar accommodated in the electrical connection box (see, for example, Japanese Patent Application Laid-open No. 2016-7101). For example, the current sensor includes various members required for detection of magnetism, such as a magnetic detection element (hall element, and the like), and a case that accommodates these various components, and the current sensor is assembled to a casing of the electrical connection box.

Incidentally, in this type of the electrical connection box, a current sensor is accommodated in an accommodation chamber of the casing, and the case of the current sensor is held in the accommodation chamber. For this reason, there is room for improvement in the conventional electrical connection box from a viewpoint of reduction of the number of parts. Note that Japanese Patent Application Lid-open No. 2006-166528 discloses a technology in which, when various components of a current sensor are disposed in a mold of a casing of an electrical connection box and the casing of the electrical connection box is formed using the mold, the various components of the current sensor are accommodated in the casing by integrating the various components at a predetermined position of the casing.

### SUMMARY OF THE INVENTION

An object of the present invention is to provide an electrical connection box in which the number of parts can be reduced.

In order to achieve the above mentioned object, an electrical connection box according to one aspect of the present invention includes a conductor that is an object to be energized, a current measurement device that measures current flowing through a current measurement target part of the conductor and outputs an output signal based on the measured current, and a casing in that the conductor and the current measurement device are accommodated, wherein the current measurement device includes a magnetic sensor that measures the current flowing through the current measurement target part, a substrate that outputs the output signal based on an input signal input from the magnetic sensor, and a magnetic shield member in which the magnetic sensors, the substrate, and the current measurement target part are disposed, the magnetic shield member being configured to shield magnetism between inside and outside of the magnetic shield member, and the casing includes a sensor accommodation chamber configured to accommodate the magnetic sensor and the substrate, a position of a magnetic detection element of the magnetic sensor with respect to the current measurement target part being arranged at a magnetic detection enabling position in the sensor accommodation chamber, and the magnetic sensor and the substrate being fixed to the sensor accommodation chamber by a fixing member, a shield insertion port into which the magnetic shield member is inserted, and a shield holding chamber formed at positions where relative displacement with respect to the sensor accommodation chamber is impossible, the shield holding chamber being configured to hold the magnetic shield member inserted from the shield insertion port at an accommodation position.

According to another aspect of the present invention, in the electrical connection box, the magnetic sensor may be a Hall IC having a Hall element as the magnetic detection element.

According to still another aspect of the present invention, in the electrical connection box, the shield holding chamber may be a space into which a held portion of the magnetic shield member is inserted together with insertion of the magnetic shield member into the casing, and the shield holding chamber may include a press-fitting part into which the held portion is press-fitted together with the insertion of the held portions.

According to still another aspect of the present invention, in the electrical connection box, the shield holding chamber may be a space into which a held portion of the magnetic shield member is inserted together with insertion of the magnetic shield member into the casing, a holding structure may be provided between the held portion and the shield holding chamber to hold the held portion and the shield holding chamber relative to each other, and the holding structure may include a projecting first locked part provided on one of the held portion and the shield holding chambers, a first locking part provided on the other of the held portion and the shield holding chamber, the first locking part being configured to lock, by bringing the first locked part into contact with the first locking part, movement in a direction opposite to an advance direction of the held portion at the time of the insertion of the held portion into the shield holding chamber, a projecting second locked part provided on one of the held portion and the shield holding chamber, and a second locking part provided on the other of the held portion and the shield holding chamber, the second locking part being configured to lock, by bringing the second locked part into contact with the second locking part, movement in the advance direction of the held portion at the time of insertion of the held portions into the shield holding chamber.

According to still another aspect of the present invention, in the electrical connection box, the casing may be an assembly of a plurality of casing members having at least a first casing member and a second casing member assembled to the first casing member, the first casing member may have the conductor disposed inside and the shield insertion port, the second casing member may have the sensor accommodation chamber and the shield holding chamber, and the magnetic sensor and the substrate may be fixed to the sensor accommodation chamber by the fixing member.

The above and other objects, features, advantages and technical and industrial significance of this invention will be better understood by reading the following detailed description of presently preferred embodiment of the invention, when considered in connection with the accompanying drawings.

### BRIEF DESCRIPTION OF THE DRAWINGS

FIG. 1 is a perspective view illustrating an electrical connection box according to an embodiment;

FIG. 2 is a plan view illustrating the electrical connection box according to the embodiment;

FIG. 3 is an exploded perspective view illustrating the electrical connection box according to the embodiment;

FIG. 4 is an enlarged view of a portion A in FIG. 2;

FIG. 5 is an exploded perspective view of a current sensor;

FIG. 6 is a cross-sectional view taken along a line X-X in FIG. 4;

FIG. 7 is a plan view of a casing (second casing member), which is an enlarged view of a periphery of a sensor accommodation chamber;

FIG. 8 is a perspective view of a casing (first casing member);

FIG. 9 is a cross-sectional view taken along a line Y1-Y1 in FIG. 4;

FIG. 10 is a cross-sectional view taken along a line Y2-Y2 in FIG. 4;

FIG. 11 is a cross-sectional view taken along a line Y3-Y3 in FIG. 4;

FIG. 12 is a cross-sectional view illustrating the first casing member and the second casing member before assembling;

FIG. 13 is a cross-sectional view illustrating the first casing member and the second casing member after assembling;

FIG. 14 is a cross-sectional view illustrating a magnetic shield member before attachment;

FIG. 15 is a plan view illustrating a current sensor according to a modification;

FIG. 16 is a cross-sectional view taken along a line Z1-Z1 in FIG. 15;

FIG. 17 is a cross-sectional view taken along a line Z2-Z2 in FIG. 15; and

FIG. 18 is a cross-sectional view taken along a line Z3-Z3 of FIG. 15.

### DETAILED DESCRIPTION OF THE PREFERRED EMBODIMENTS

An embodiment of an electrical connection box according to the present invention will be described hereafter in detail with reference to the drawings. Note that the present invention is not limited to this embodiment.

### EMBODIMENT

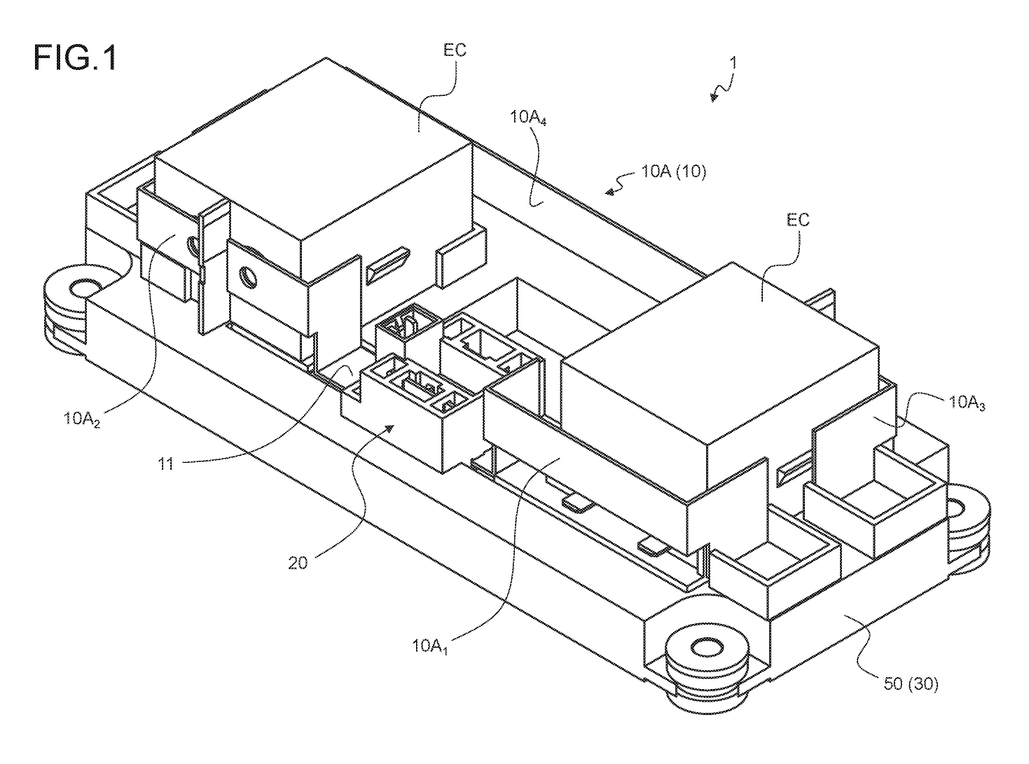

An embodiment of an electrical connection box according to the present invention is described with reference to FIGS. 1 to 14.

Reference numeral 1 in FIGS. 1 to 3 denotes the electrical connection box of the present embodiment. The electrical connection box 1 includes a conductor 10 serving as an object to be energized, a current measurement device 20 that measures current flowing through a current measurement target part 11 of the conductor 10 and outputs an output signal relating to the measured current, and a casing 30 that accommodates the conductor 10 and the current measurement device 20. Note that in each of these drawings, a cover member to be described later of the casing 30 is removed, and the conductor 10 and the like are exposed.

The conductor 10 is a member made of a conductive material such as metal. The conductor 10 is electrically connected to each of electronic components EC such as a relay and an electric wire (not illustrated), for example, and an energization path through which current flows is provided between a side of the electronic component EC and a side of the electric wire. In the conductor 10, the current flowing through the energization path is measured. Therefore, the conductor 10 includes the current measurement target part 11 as a measurement position of the current on the energization path.

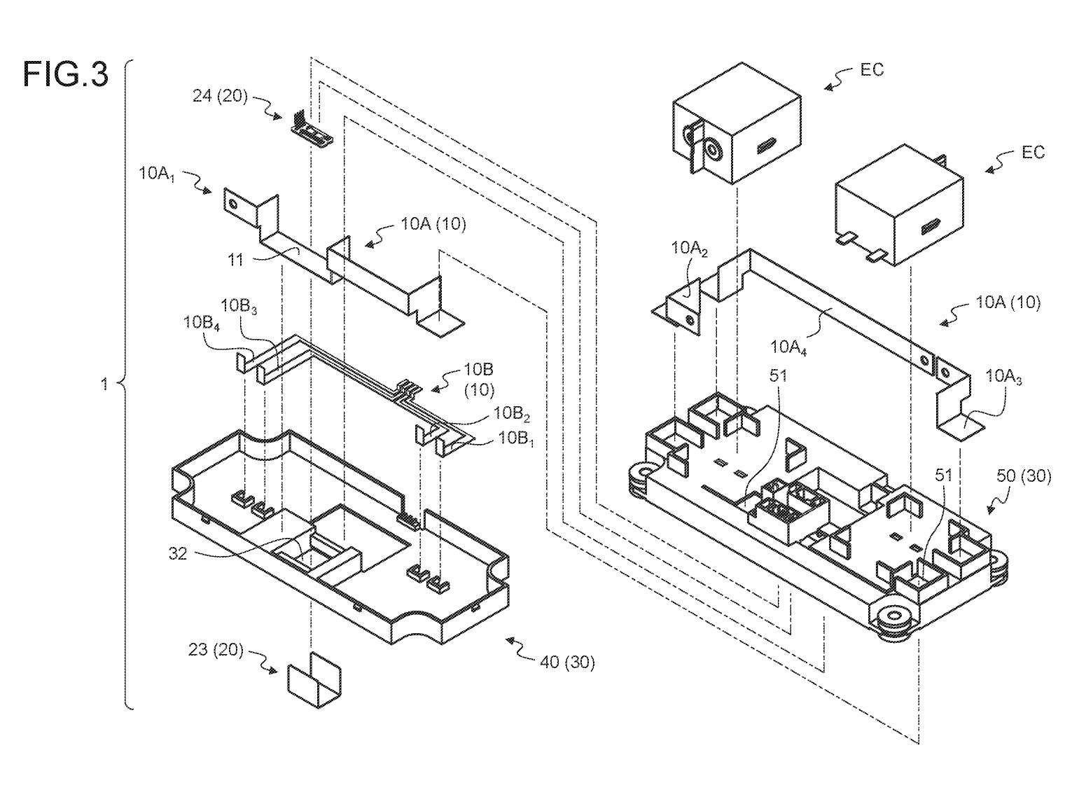

In this example, a plate-shaped bus bar formed by using a conductive metal plate material (for example, a copper plate) as a base material is prepared as the conductor 10. The electrical connection box 1 of this example accommodates a conductor for high voltage (hereinafter referred to as a “high-voltage conductor”) 10A, a conductor for low voltage (hereinafter referred to as a “low-voltage conductor”) 10B (FIG. 3). The high-voltage conductor 10A includes plate-shaped first to fourth conductive members 10A₁ to 10A₄. The low-voltage conductor 10B includes plate-shaped first to fourth conductive members 10B₁ to 10B₄. The electrical connection box 1 of this example measures current flowing through the high-voltage conductor 10A, and the rectangular current measurement target part 11 is provided on the first conductive member 10A₁. With respect to the current measurement target part 11, a width direction is a direction along a plane of the current measurement target part 11 and orthogonal to a direction in which the current flows.

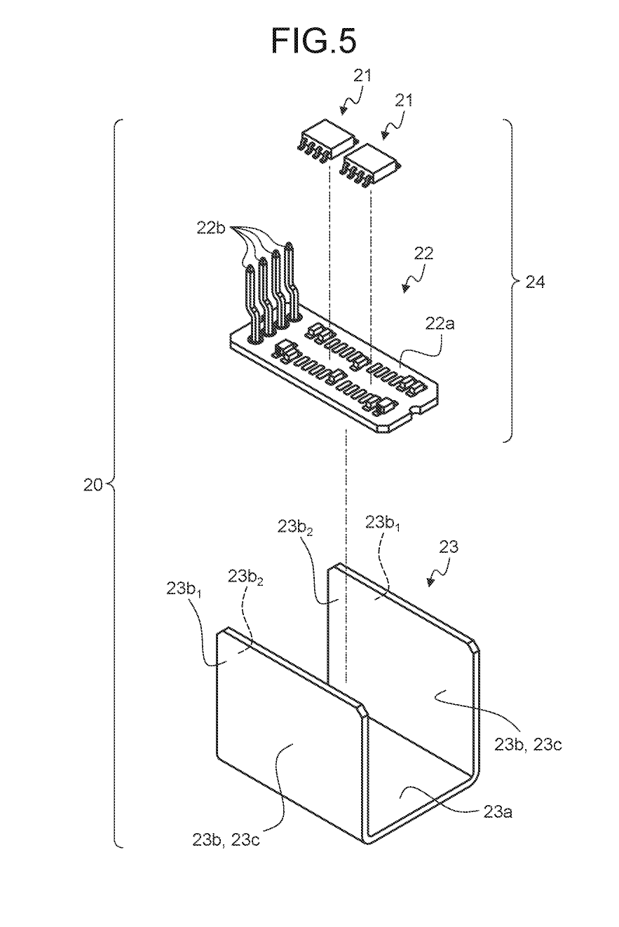

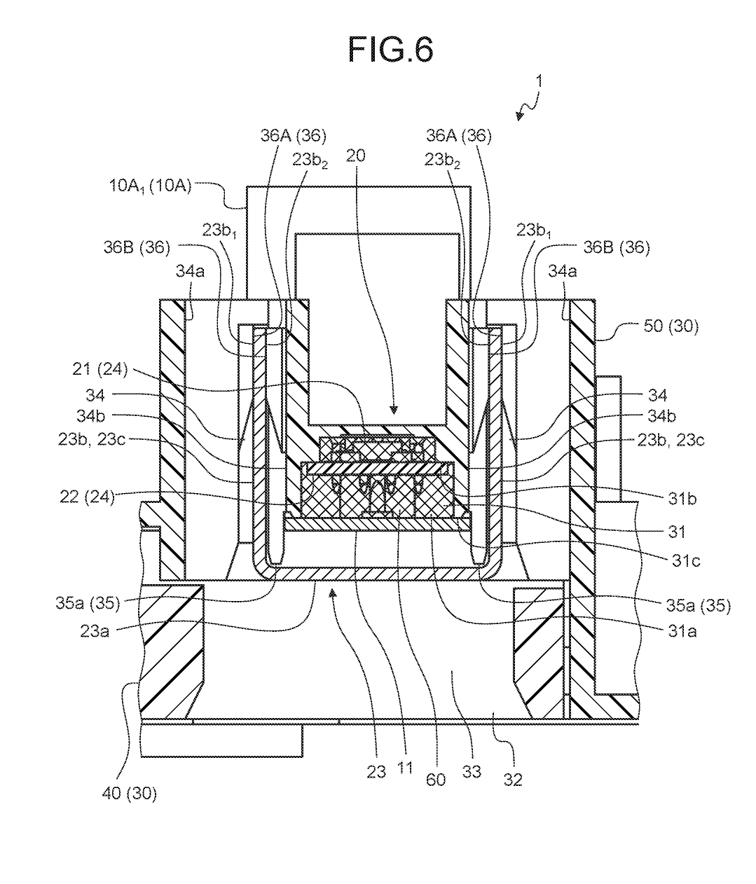

The current measurement device 20 is disposed close to the current measurement target part 11 in the high-voltage conductor 10A (FIGS. 1, 2 and 4). The current measurement device 20 includes a magnetic sensor 21 that measures the current flowing through the current measurement target part 11, a substrate 22 that outputs an output signal based on an input signal input from the magnetic sensors 21, and a magnetic shield member 23 in which the magnetic sensor 21, the substrate 22, and the current measurement target part 11 are disposed, and which shields magnetism between inside and outside of the magnetic shield member 23 (FIGS. 5 and 6).

The magnetic sensor 21 detects a magnetic field according to the current flowing through the current measurement target part 11 by a magnetic detection element (not illustrated), and outputs an output signal according to the magnetic field. The magnetic detection element is disposed at a magnetic detection enabling position spaced apart from the current measurement target part 11. The magnetic detection enabling position is a position at which the magnetic detection element can detect the magnetic field generated according to the current flowing through the current measurement target part 11.

The magnetic sensor 21 is electrically connected to the substrate 22, and causes the substrate 22 to input the output signal according to the magnetic field. The substrate 22 generates and outputs an output signal based on the input signal from the magnetic sensor 21. For example, the substrate 22 includes a plate-shaped main body 22a on which an electric circuit is formed, and a terminal 22b electrically connected to the electric circuit (FIG. 5), and outputs the generated output signal from the terminal 22b. A mating terminal of a mating connector (not illustrated) is fitted with and electrically connected to the terminal 22b. The output signal from the substrate 22 is transmitted, via the mating connector, to a signal transmission target such as an electronic control device (not illustrated), for example.

In this example, a Hall integrated circuit (IC) is used as the magnetic sensor 21. Although not illustrated, the Hall IC includes a Hall element serving as the magnetic detection element and an amplifier circuit that amplifies an output signal of the Hall element. For example, the Hall element is disposed at a position (the magnetic detection enabling position) at a predetermined space from an approximate center in the width direction of the current measurement target part 11 in a direction orthogonal to the plane of the current measurement target part 11. The Hall IC is accommodated in the casing 30 such that the Hall element can be disposed as described above. The Hall IC converts a detected magnetic field into a Hall voltage by the Hall element, amplifies a signal based on the Hall voltage by the amplifier circuit, and then outputs an output signal of the Hall voltage. The substrate 22 calculates, for example, a current value based on an input signal of the Hall voltage input from the Hall IC, and outputs an output signal based on the current value from the terminal 22b.

In this current measurement device 20, the magnetic sensor 21 and the substrate 22 are physically and electrically connected and integrated with each other.

The magnetic shield member 23 is made of a plate-shaped highly permeable magnetic material such as a silicon steel plate as a base material. The magnetic shield member 23 of this example is formed in a U-shape, and has a rectangular base wall portion 23a, and standing wall portions 23b protruding in the same direction from two opposed sides of the base wall portion 23a (FIGS. 5 and 6). A plane of the base wall portion 23a is opposed to a plane of the current measurement target part 11 on a side opposite to a side of the magnetic sensor 21, and the base wall portion 23a is disposed at a position spaced apart from the plane on the opposite side. Each of the standing wall portions 23b is vertically arranged to the plane of the base wall portion 23a. At an accommodation position in the casing 30, the magnetic shield member 23 covers the current measurement target part 11 by the base wall portion 23a at an interval, and covers the magnetic sensor 21, the substrate 22, and the current measurement target part 11 by the standing wall portions 23b at intervals, such that the magnetic sensor 21, the substrate 22, and the current measurement target part 11 are disposed in the magnetic shield member 23 (FIG. 6). The accommodation position of the magnetic shield member 23 in the casing 30 is a position where the magnetic field generated according to the current flowing through the current measurement target part 11 can be collected.

The casing 30 is formed of an insulating material such as a synthetic resin. The casing 30 is an assembly of a plurality of casing members at least having a first casing member 40 and a second casing member 50 (FIG. 3). The casing 30 of this example includes the first casing member 40 and the second casing member 50 assembled with each other, and although not illustrated, a third casing member serving as a cover member covering the first casing member 40 and the second casing member 50. The third casing member covers the conductor 10, the electronic components EC, and the like which are exposed in FIG. 1.

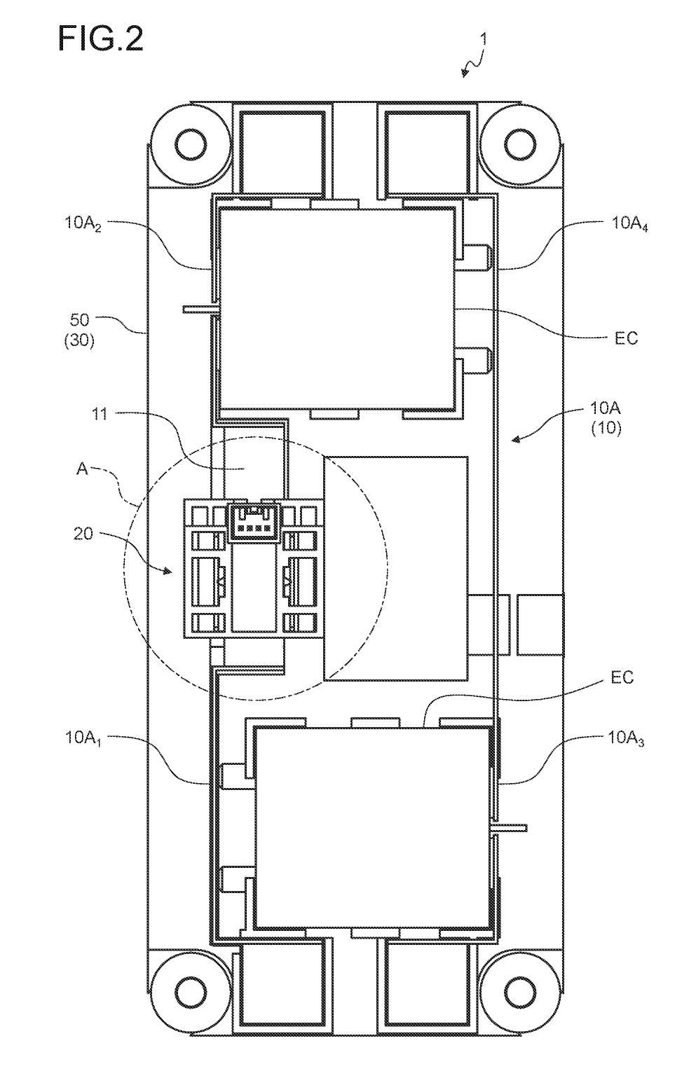

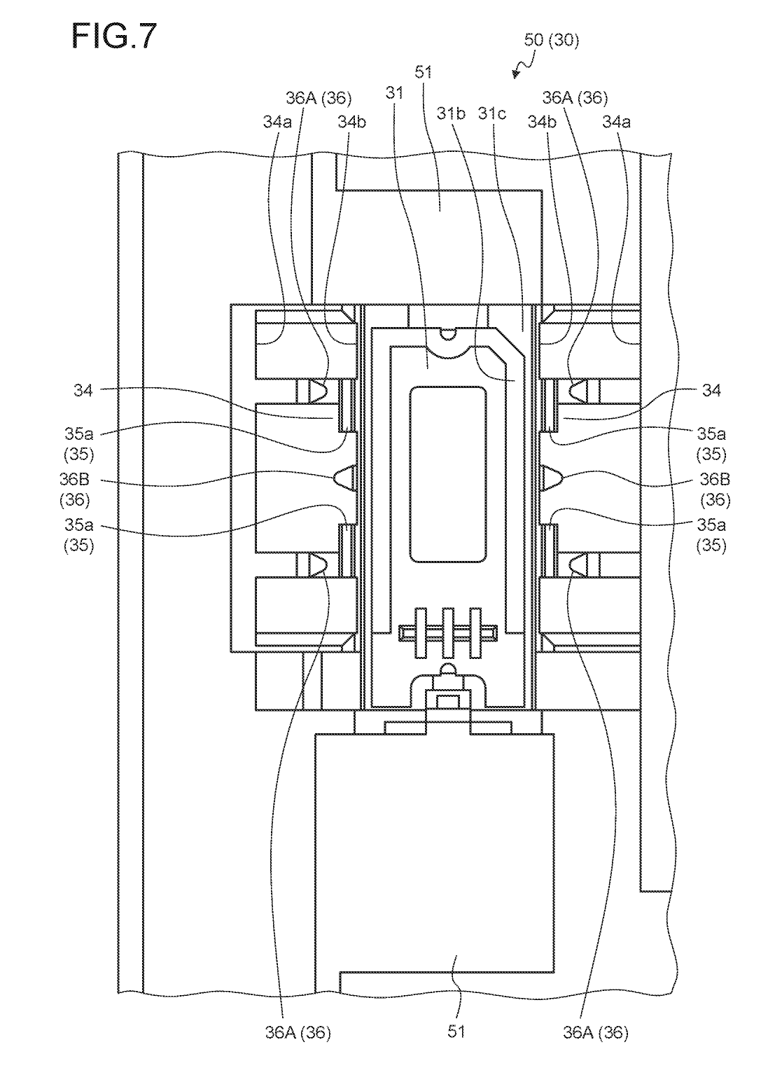

The casing 30 includes a sensor accommodation chamber 31 accommodating the magnetic sensor 21 and the substrate 22 (FIGS. 6 and 7). The sensor accommodation chamber 31 is a space in which a position of the magnetic detection element of the magnetic sensor 21 with respect to the current measurement target part 11 is disposed at the magnetic detection enabling position, and the magnetic sensor 21 and the substrate 22 are fixed in the chamber by a fixing member 60 (FIG. 6). In FIG. 6, for convenience of illustration, the fixing member 60 is illustrated by cross hatching (the same applies hereinafter). The sensor accommodation chamber 31 has an opening 31a for insertion of the magnetic sensor 21 and the substrate 22. In the sensor accommodation chamber 31, an integrated product (hereinafter referred to as a “sensor assembly”) 24 (FIG. 2) which is an assembly of the magnetic sensor 21 and the substrate 22 is inserted from the opening 31a and accommodated in the chamber. The interior of the sensor accommodation chamber 31 of this example is formed as an internal space having the rectangular opening 31a, and a direction orthogonal to the opening 31a is an insertion direction of the sensor assembly 24. The sensor assembly 24 is inserted into the sensor accommodation chamber 31 in a direction orthogonal to a plane of the main body 22a of the substrate 22. Here, the sensor assembly 24 is inserted from the side of the magnetic sensor 21, and the magnetic sensor 21 is accommodated behind the substrate 22. Note that the sensor assembly 24 may be inserted from a side of the substrate 22, and the substrate 22 may be accommodated behind the magnetic sensor 21.

The magnetic sensor 21 and the substrate 22 accommodated in the chamber are fixed such that the position of the magnetic detection element of the magnetic sensor 21 in the chamber is at the magnetic detection enabling position. For this purpose, a sensor locking part 31b that locks the inserted sensor assembly 24 is provided in the sensor accommodation chamber 31 (FIGS. 6 and 7). For example, the sensor locking part 31b is a wall surface with which a part or the whole of a peripheral edge portion of the plane of the main body 22a of the substrate 22 is brought to come into contact. The sensor assembly 24 accommodated in the sensor accommodation chamber 31 is fixed by the fixing member 60 in the chamber. For example, a cured body of a potting liquid filled in the sensor accommodation chamber 31 after the sensor assembly 24 is accommodated therein is used for the fixing member 60. The fixing member 60 is provided so as to be flush with the opening 31a of the sensor accommodation chamber 31, for example.

Here, in the sensor accommodation chamber 31, an end surface on a side of the opening 31a is used as a locking part (hereinafter referred to as a “conductor locking part”) 31c of the current measurement target part 11 (FIGS. 6 and 7). The conductor locking part 31c is a part with which a part or the whole of a peripheral edge portion in the plane of the current measurement target part 11 can be brought to come into contact, for example, and regulates a position of the current measurement target part 11 with respect to the sensor accommodation chamber 31. That is, it can be said that the conductor locking part 31c and the above-described sensor locking part 31b regulate the position of the magnetic detection element of the magnetic sensor 21 with respect to the current measurement target part 11. Therefore, the sensor locking part 31b and the conductor locking part 31c are formed such that the position of the magnetic detection element with respect to the current measurement target part 11 is at the magnetic detection enabling position. Note that, as will be described later, the current measurement target part 11 and the conductor locking part 31c approach each other as the first casing member 40 and the second casing member 50 are assembled. Therefore, the conductor locking part 31c does not necessarily have to be in contact with the current measurement target part 11.

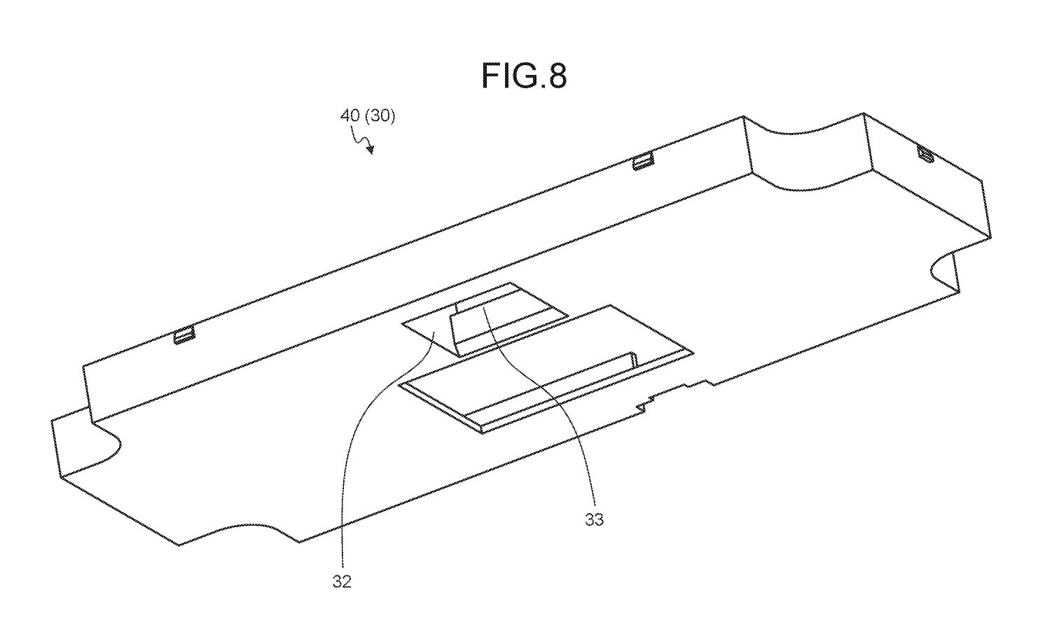

Furthermore, the casing 30 includes a shield insertion port 32 (FIGS. 6 and 8) into which the magnetic shield member 23 is inserted. The shield insertion port 32 is an opening that accommodates the magnetic shield member 23 to the accommodation position in the casing 30. As described above, the magnetic shield member 23 covers, at the accommodation position in the casing 30, the current measurement target part 11 by the base wall portion 23a at an interval, and covers the magnetic sensor 21, the substrate 22, and the current measurement target part 11 by the standing wall portions 23b at intervals. Accordingly, in the casing 30, the shield insertion port 32 is provided on an opposite side of the sensor accommodation chamber 31 with respect to the current measurement target part 11. In the casing 30, the magnetic shield member 23 is inserted through the shield insertion port 32 in the same direction as the insertion direction of the sensor assembly 24 with respect to the sensor accommodation chamber 31, and is guided to the accommodation position in the same direction. At that time, the magnetic shield member 23 is inserted into the shield insertion port 32 from a free end side of each of the standing wall portions 23b.

The magnetic shield member 23 inserted from the shield insertion port 32 is guided to the accommodation position through a space 33 (FIGS. 6 and 8) of the casing 30 communicated with the shield insertion port 32. The casing 30 is provided with shield holding chambers 34 (FIGS. 6 and 7) that hold the magnetic shield member 23 at the accommodation position. The shield holding chambers 34 are spaces into which held portions 23c (FIGS. 5 and 6) of the magnetic shield member 23 are inserted together with the insertion of the magnetic shield member 23 into the casing 30. In the magnetic shield member 23 of this example, the standing wall portions 23b are used as the held portions 23c. Accordingly, the shield holding chamber 34 is provided for each held portion 23c.

Here, the magnetic shield member 23 is disposed outside the sensor accommodation chamber 31. Therefore, the shield holding chambers 34 are disposed to face each other so as to cover the sensor accommodation chamber 31 from sides (FIGS. 6 and 7). Standing walls 35 are provided between the shield holding chambers 34 and the sensor accommodation chamber 31. Further, in the standing wall 35, end surfaces on a side of the shield insertion port 32 are used as shield locking parts 35a (FIGS. 6 and 7). Each of the shield locking parts 35a is a part capable of locking the base wall portion 23a of the magnetic shield member 23, and regulates a position of the magnetic shield member 23 not to be inserted farther than the locking position. Each of the shield locking parts 35a sets its position such that even when the magnetic shield member 23 is inserted until the base wall portion 23a is locked, the locking position falls within a range of the accommodation position of the magnetic shield member 23 in the casing 30. The “within a range of the accommodation position of the magnetic shield member 23” means that it is within a range of a position where the magnetic shield member 23 can exert its function (magnetism collecting function to be described below) in the current measurement device 20. For example, the magnetic shield member 23 is inserted through the shield insertion port 32, and is accommodated at the accommodation position in the casing 30 by inserting each of the standing wall portions 23b (held portions 23c) into each of the shield holding chambers 34 until the base wall portion 23a is locked with each of the shield locking parts 35a. Accordingly, each of the shield locking parts 35a can determine a relative position of the magnetic shield member 23 with respect to the magnetic sensor 21, the substrate 22, and the current measurement target part 11. Therefore, the magnetic sensor 21, the substrate 22, and the current measurement target part 11 can be disposed in the magnetic shield member 23, and the magnetic field generated according to the current flowing through the current measurement target part 11 can be collected by the magnetic shield member 23.

In the casing 30, the shield holding chambers 34 are formed at positions where relative displacement with respect to the sensor accommodation chamber 31 is impossible, and the standing walls 35 and the shield locking parts 35a are also disposed at positions where the relative displacement with respect to the sensor accommodation chamber 31 is impossible. With this configuration, when the magnetic shield member 23 is accommodated at the accommodation position in the casing 30, it is possible to suppress the relative displacement of the magnetic shield member 23 with respect to the magnetic sensor 21, the substrate 22, and the current measurement target part 11. Therefore, here, it is possible to suppress deviation in a magnetism collecting effect caused by the magnetic shield member 23.

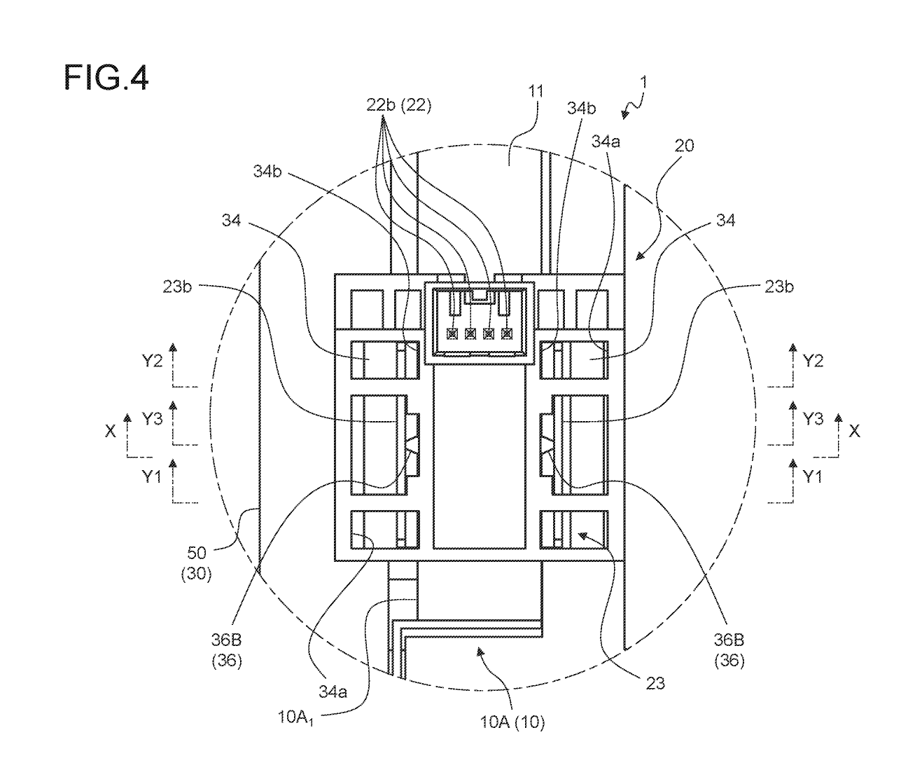

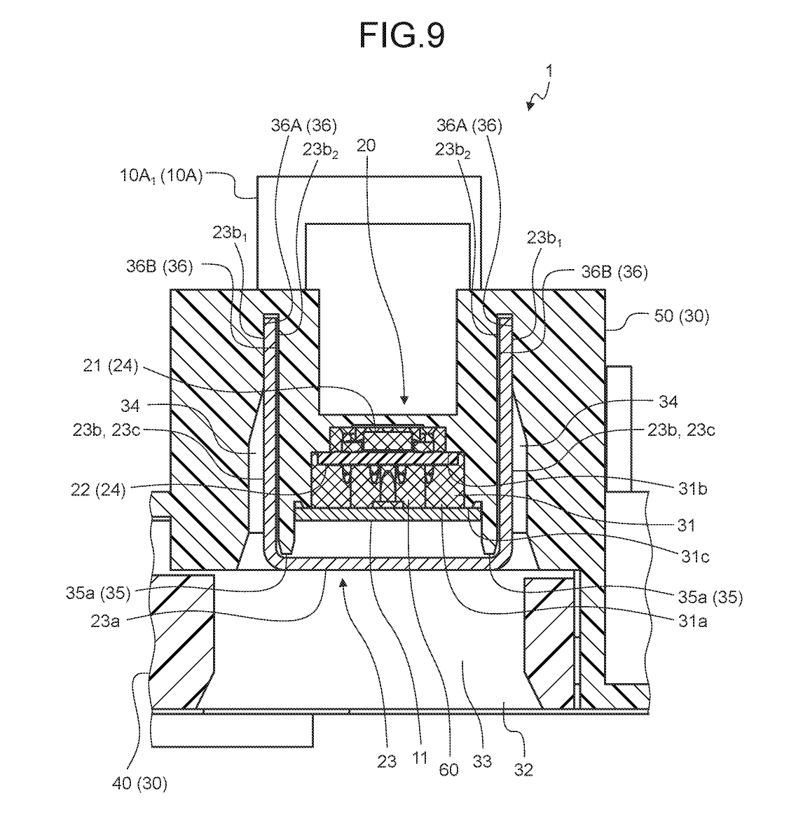

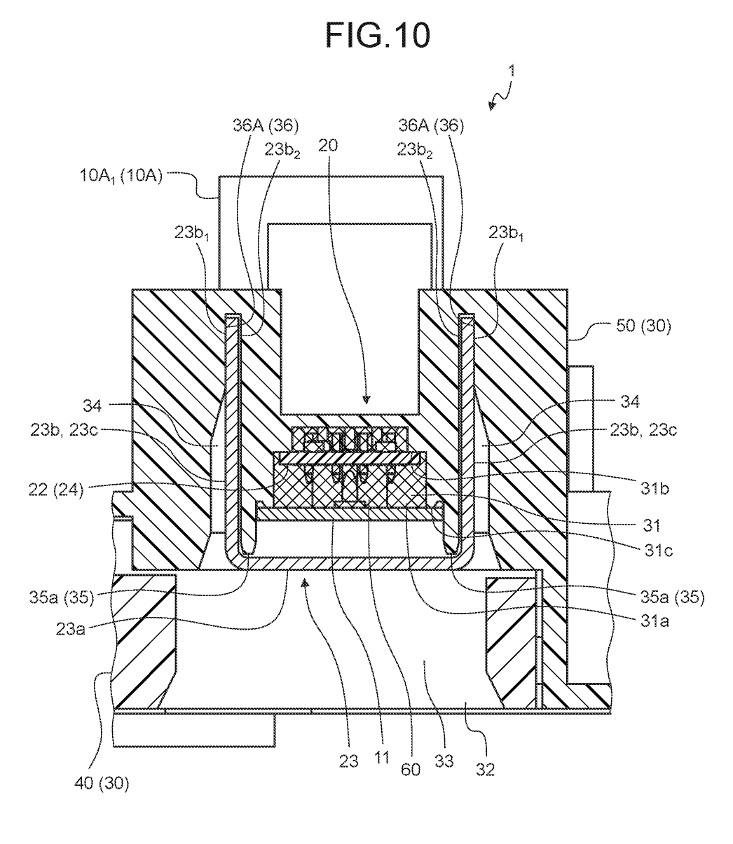

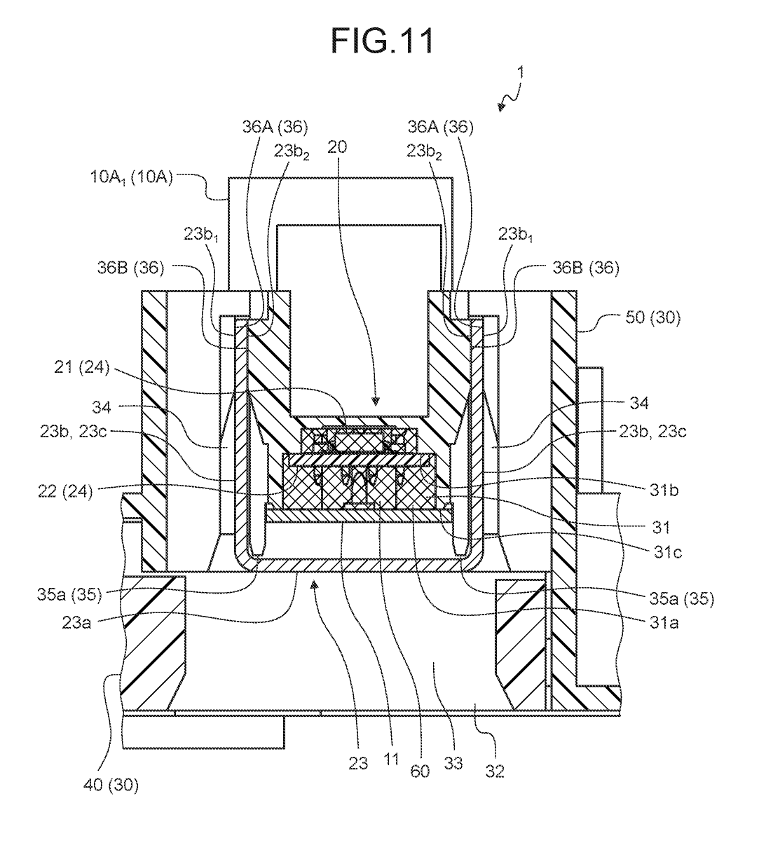

The shield holding chambers 34 hold the standing wall portions 23b (held portions 23c) so as to hold the magnetic shield member 23 at the accommodation position in the casing 30. The shield holding chambers 34 of this example include press-fitting parts 36 into which the standing wall portions 23b (held portions 23c) are press-fitted together with the insertion of the standing wall portions 23b (held portions 23c) (FIGS. 4 and 9 to 11). In this example, first press-fitting parts 36A (FIGS. 9 and 10) to be brought into contact with first wall surfaces 23b₁ on outer sides of the standing wall portions 23b (held portions 23c) and second press-fitting parts 36B (FIG. 11) to be brought into contact with second wall surfaces 23b₂ on inner sides of the standing wall portions 23b (held portions 23c) are disposed alternately as the press-fitting parts 36 such that the total number of the first press-fitting part 36A and the second press-fitting part 36B becomes at least three.

For example, the shield holding chamber 34 has first wall surfaces 34a opposed to the first wall surfaces 23b₁ of the standing wall portions 23b (held portions 23c) with intervals, and second wall surfaces 34b opposed to the second wall surfaces 23b₂ of the standing wall portions 23b (held portions 23c) with spaces (FIGS. 4, 6, and 7). The first press-fitting parts 36A are protrusions protruding from the first wall surfaces 34a toward the first wall surfaces 23b₁ of the standing wall portions 23b (held portions 23c) inserted into the shield holding chamber 34, and portions where the protrusions are brought into contact with the first wall surfaces 23b₁ are extended along the insertion direction of the standing wall portions 23b (held portions 23c) into the shield holding chamber 34. Tip ends in a protruding direction of the first press-fitting parts 36A of this example are formed into arc shapes so as to be in line-contact with the first wall surfaces 23b₁ upon press-fitting. In addition, the second press-fitting parts 36B are protrusions protruding from the second wall surfaces 34b toward the second wall surfaces 23b₂ of the standing wall portions 23b (held portions 23c) inserted into the shield holding chamber 34, and portions where the protrusions are brought into contact with the second wall surfaces 23b₂ are extended in the insertion direction of the standing wall portions 23b (held portions 23c) into the shield holding chamber 34. Tip ends in a protruding direction of the second press-fitting parts 36B of this example are formed into arc shapes so as to be in line-contact with the second wall surfaces 23b₂ upon press-fitting. Here, one first press-fitting part 36A and two second press-fitting parts 36B with the first press-fitting part 36A interposed therebetween are alternately disposed. Accordingly, the standing wall portions 23b (held portions 23c) are press-fitted by being inserted into the shield holding chambers 34, and are held by the first press-fitting parts 36A and the second press-fitting parts 36B. Therefore, the magnetic shield member 23 can keep an accommodated state at the accommodation position in the casing 30.

Note that, as described above, the casing 30 of this example is a divided structure having the first casing member 40 and the second casing member 50. Therefore, the various configurations of the casing 30 described so far are appropriately provided in the first casing member 40 and the second casing member 50. In this example, the first casing member 40 is provided with the conductor 10 (specifically, the first conductive member 10A₁ of the high-voltage conductor 10A), and has the shield insertion port 32 and the space 33. In addition, the second casing member 50 has the sensor accommodation chamber 31 (including the sensor locking part 31b and the conductor locking part 31c), the shield holding chambers 34 (including the press-fitting parts 36), and the standing walls 35 (including the shield locking parts 35a).

An installation process of the current measurement device 20 in the electrical connection box 1 will be described as follows.

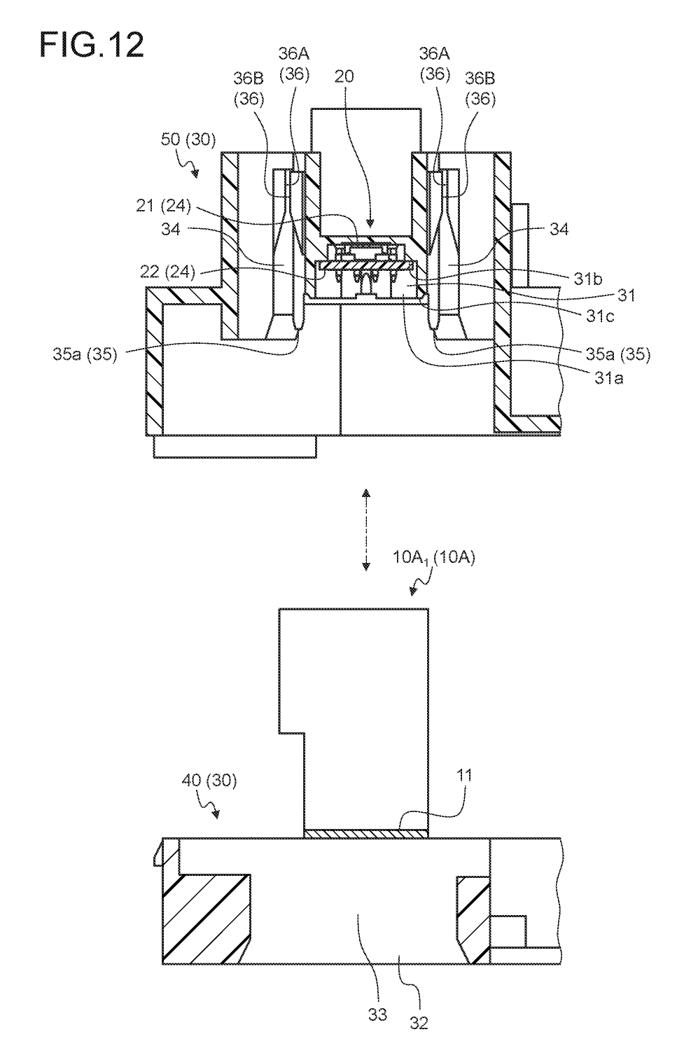

First, the magnetic sensor 21 and the substrate 22 are fixed to the sensor accommodation chamber 31 of the second casing member 50 by the fixing member 60 (FIG. 12). In this example, the sensor assembly 24 is inserted into the sensor accommodation chamber 31, and the main body 22a of the substrate 22 is brought into contact and locked with the sensor locking part 31b, thereby the sensor assembly 24 is installed at a predetermined position in the sensor accommodation chamber 31. In the second casing member 50, the sensor accommodation chamber 31 is filled with the potting liquid in an installed state, and by curing the potting liquid, the fixing member 60 made of the cured body of the potting liquid is formed, and the sensor assembly 24 is fixed at the predetermined position in the sensor accommodation chamber 31. Note that illustration of the fixing member 60 is omitted here. Furthermore, although not illustrated in FIG. 12, the second to fourth conductive members 10A₂ to 10A₄ of the high-voltage conductor 10A are installed in the second casing member 50.

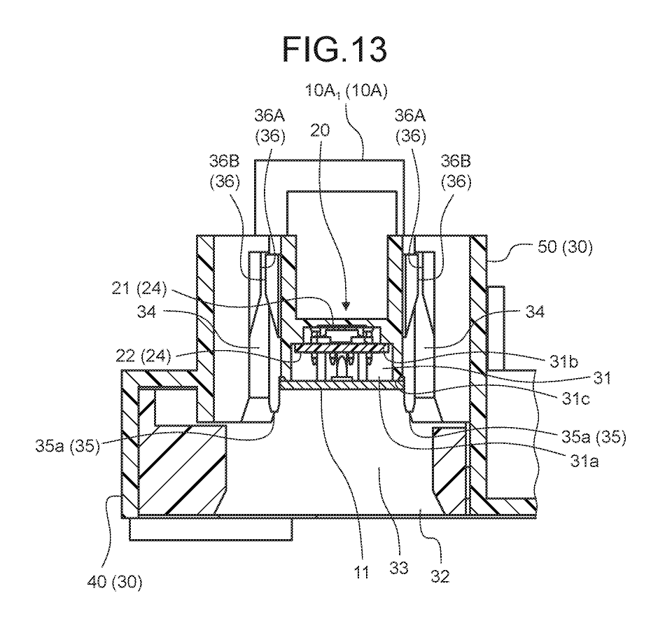

Next, the first conductive member 10A₁ of the high-voltage conductor 10A is installed on the first casing member 40 (FIG. 12), and thereafter, the second casing member 50 to which the magnetic sensor 21 and the substrate 22 are fixed is assembled to the first casing member 40 (FIG. 13). Although not illustrated in the drawings, the low-voltage conductor 10B is also installed on the first casing member 40. The current measurement target part 11 of the first conductive member 10A₁ is installed close to the conductor locking part 31c or at a position locked by the conductor locking part 31c as the assembly of the first casing member 40 and the second casing member 50 is completed. Note that through holes 51 (FIGS. 3 and 7) through which the first conductive member 10A₁ is inserted at the time of assembly to the first casing member 40 are formed in the second casing member 50.

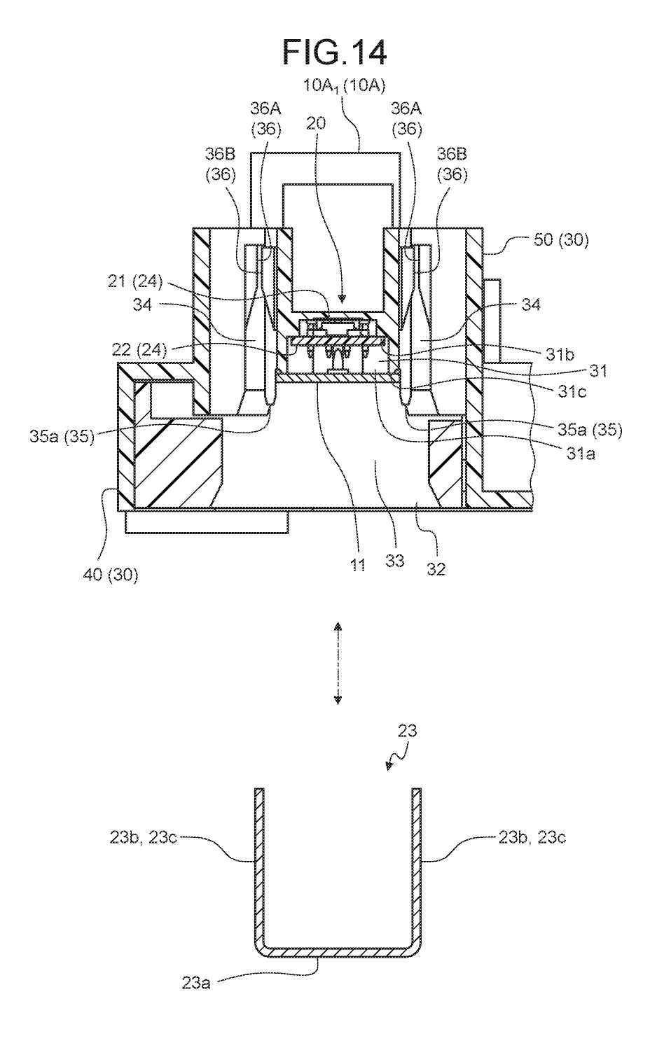

Thereafter, the magnetic shield member 23 is attached to the casing 30. The magnetic shield member 23 is inserted from the shield insertion port 32 (FIG. 14), and each of the standing wall portions 23b (held portions 23c) is press-fitted into the shield holding chamber 34 (FIG. 6).

The current measurement device 20 is installed on the casing 30 in this manner.

As described above, in the electrical connection box 1 of the present embodiment, the current measurement device 20 is formed by accommodating and fixing the magnetic sensor 21 and the substrate 22 in the sensor accommodation chamber 31 of the casing 30, inserting the magnetic shield member 23 from the shield insertion port 32 to the accommodation position in the casing 30, and accommodation the magnetic shield member 23 at the predetermined position with respect to the magnetic sensor 21, the substrate 22, and the current measurement target part 11. In particular, in the electrical connection box 1 of this example, by accommodating and fixing the magnetic sensor 21 and the substrate 22 in the sensor accommodation chamber 31 of the second casing member 50, and installing the conductor 10 on the first casing member 40 and assembling the first casing member 40 and the second casing member 50, the magnetic detection element of the magnetic sensor 21 is disposed at a predetermined position of the electric conductor 10 with respect to the current measurement target part 11. In the electrical connection box 1, the magnetic shield member 23 is accommodated at the predetermined position with respect to the magnetic sensor 21, the substrate 22, and the current measurement target part 11 by inserting the magnetic shield member 23 through the shield insertion port 32 of the first casing member 40, and holding the magnetic shield member 23 by the shield holding chamber 34 of the second casing member 50. In the electrical connection box 1 of this example, the current measurement device 20 is formed in this manner. Therefore, in the electrical connection box 1 of the present embodiment, the number of parts can be reduced as compared with a conventional electrical connection box. Further, with the reduction in the number of parts, it is possible to reduce physical size and weight of the electrical connection box 1, as well as the cost.

Modification

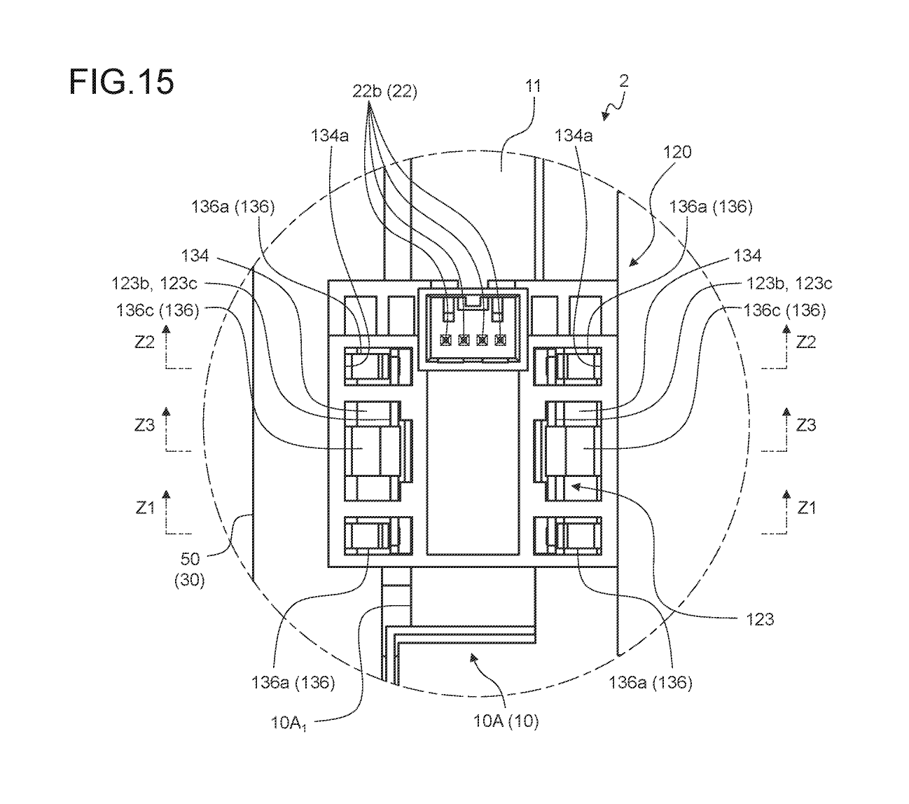

An electrical connection box 2 of the present modification is obtained by replacing the magnetic shield member 23 and the shield holding chamber 34 with a magnetic shield member 123 and a shield holding chamber 134 described below in the electrical connection box 1 of the above-described embodiment, and a holding form between the magnetic shield member and the shield holding chamber is replaced with a holding form described below (FIGS. 15 to 18).

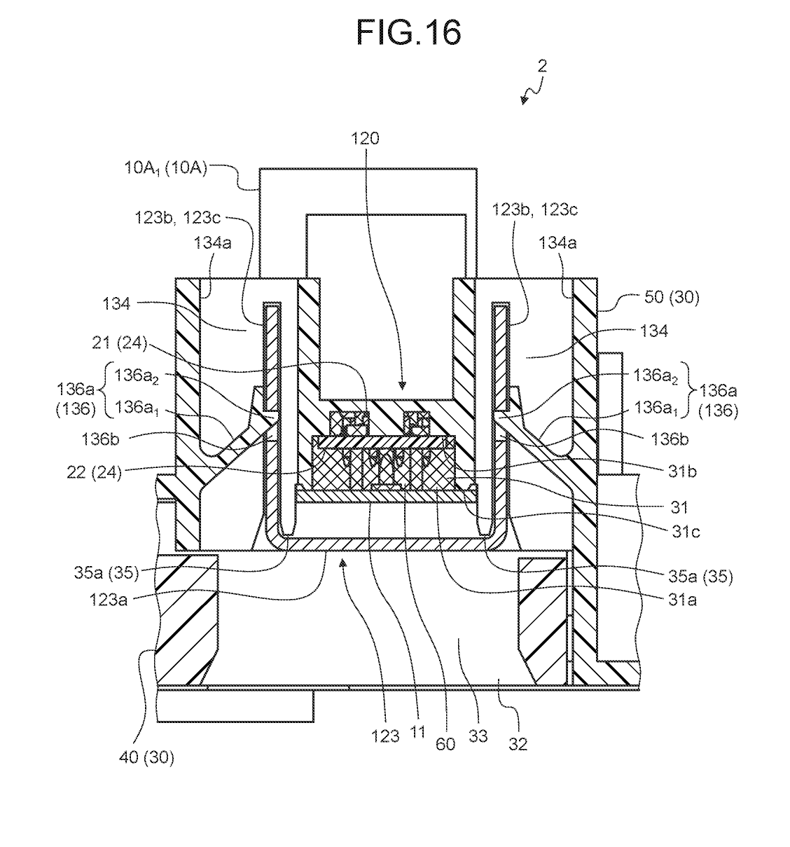

First, in a current measurement device 120 of the present modification, the magnetic shield member 123 is formed in a U-shape similarly to the magnetic shield member 23 of the embodiment, and has a base wall portion 123a and two standing wall portions 123b (FIGS. 16 to 18). Similarly to the magnetic shield member 23 of the embodiment, the magnetic shield member 123 uses the standing wall portions 123b as held portions 123c in the shield holding chamber 134.

Next, the shield holding chamber 134 of the present modification has a shape and disposition similar to those of the shield holding chamber 34 of the embodiment, and is provided for each magnetic shield member 123. Note that the shield holding chamber 134 is different from the shield holding chamber 34 of the embodiment in that the press-fitting parts 36 are not provided.

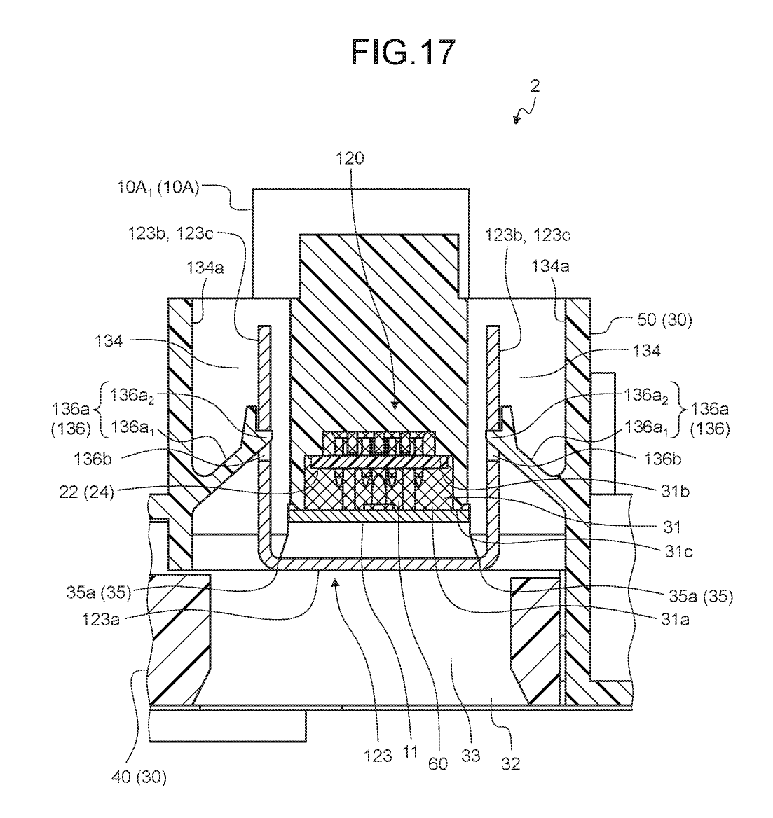

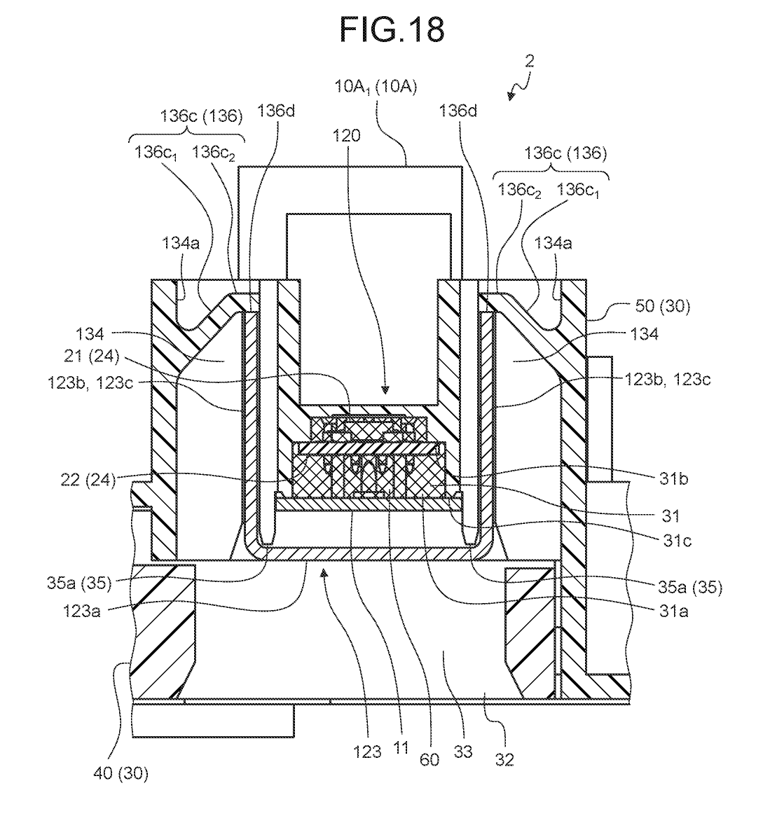

In the holding form of the present modification, the standing wall portions 123b (held portions 123c) of the magnetic shield member 123 are held by the shield holding chamber 134. Holding structures 136 are provided between the standing wall portions 123b (held portions 123c) and the shield holding chamber 134 to hold the standing wall portions 123b (held portions 123c) and the shield holding chamber 134 relative to each other. The holding structures 136 include projecting first locked parts 136a which are provided on one of the standing wall portions 123b (held portions 123c) and the shield holding chambers 134, and first locking parts 136b which are provided on the other of the standing wall portions 123b (held portions 123c) and the shield holding chambers 134, and lock, by bringing the first locked parts 136a into contact with the first locking parts 136b, movement in a direction opposite to an advance direction of the standing wall portions 123b (held portions 123c) at the time of the insertion of the standing wall portions 123b (held portions 123c) into the shield holding chambers 134 (FIGS. 16 and 17). Furthermore, the holding structures 136 include projecting second locked parts 136c which are provided on one of the standing wall portions 123b (held portions 123c) and the shield holding chambers 134, and second locking parts 136d which are provided on the other of the standing wall portions 123b (held portions 123c) and the shield holding chambers 134, and lock, by bringing the second locked parts 136c into contact with the second locking parts 136d, movement in the advance direction of the standing wall portions 123b (held portions 123c) at the time of insertion of the standing wall portions 123b (held portions 123c) into the shield holding chambers 134 (FIG. 18). In the holding structures 136, along a plane of the base wall portion 123a and along a direction orthogonal to an opposing direction of each of the standing wall portions 123b, at least one combination of the first locked part 136a and the first locking part 136b and at least one combination of the second locked part 136c and the second locking part 136d are arranged alternately.

In this example, the first locked parts 136a and the second locked parts 136c are provided in the shield holding chambers 134, and the first locking parts 136b and the second locking parts 136d are provided in the standing wall portions 123b (held portions 123c). Furthermore, in this example, two combinations of the first locked part 136a and the first locking part 136b are provided, and one combination of the second locked part 136c and the second locking part 136d is disposed between the two combinations.

The first locked parts 136a and the second locked parts 136c protrude from wall surfaces 134a on sides opposite to a side of the sensor accommodation chamber 31 of the shield holding chambers 134 toward the standing wall portions 123b (held portions 123c).

The first locked part 136a has a flexible part 136a₁ having flexibility and protruding from the wall surface 134a, and a claw 136a₂ provided at a tip end in a protruding direction of the flexible part 136a₁ (FIGS. 16 and 17). The first locking parts 136b are formed as through hole portions or groove portions into which the claws 136a₂ enter when the standing wall portions 123b (held portions 123c) are inserted into the shield holding chambers 134 and the magnetic shield member 123 is accommodated at the accommodation position in the casing 30. Here, the first locking parts 136b serving as the through hole portions are formed in the standing wall portions 123b (held portions 123c). The claws 136a₂ of the first locked parts 136a are inserted into the first locking parts 136b and then brought into contact with inner peripheral walls of the first locking parts 136b. Therefore, when the standing wall portions 23b (held portions 23c) try to move in a direction opposite to the advance direction at the time of the insertion of the standing wall portions 23b (held portions 23c), the claws 136a₂ are locked by the inner peripheral walls of the first locking parts 136b.

The second locked part 136c has a flexible part 136c₁ having flexibility and protruding from the wall surface 134a, and a claw 136c₂ provided at a tip end in a protruding direction of the flexible part 136c₁ (FIG. 18). As the second locking part 136d, an end surface on a side of a vertical installation direction of the standing wall portion 123b (held portion 123c) is used. The claws 136c₂ of the second locked parts 136c are brought into contact with the second locking parts 136d when the standing wall portions 123b (held portions 123c) are inserted into the shield holding chambers 134 and the magnetic shield member 123 is accommodated at the accommodation position in the casing 30. Therefore, even when the standing wall portions 23b (held portions 23c) try to move further in the advance direction at the time of the insertion of the standing wall portions 23b (held portions 23c), the claws 136c₂ are locked by the second locking parts 136d.

As described above, the holding structures 136 of the present modification lock, in a state where the magnetic shield member 123 is accommodated at the accommodation position in the casing 30, both the movement of the standing wall portions 23b (held portions 23c) in the advance direction at the time of the insertion of the standing wall portions 23b (held portions 23c) and the movement in the direction opposite to the advance direction. Therefore, the holding structures 136 can continue to hold the magnetic shield member 123 at a predetermined position with respect to the magnetic sensor 21, the substrate 22, and the current measurement target part 11. Therefore, the electrical connection box 2 of the present modification can obtain an effect similar to that of the electrical connection box 1 of the embodiment, and at the same time, can enhance an effect of suppressing the displacement of the magnetic shield member 123 with respect to the magnetic sensor 21, the substrate 22, and the current measurement target part 11, as compared with the electrical connection box 1.

In an electrical connection box according to the present embodiment, a current measurement device is formed by accommodating and fixing a magnetic sensor and a substrate in a sensor accommodation chamber of a casing, inserting a magnetic shield member from a shield insertion port to an accommodation position in the casing, and accommodating the magnetic shield member at a predetermined position with respect to the magnetic sensor, the substrate, and a current measurement target part. Therefore, in the electrical connection box, the number of parts can be reduced as compared with a conventional electrical connection box. Further, with the reduction in the number of parts, it is possible to reduce physical size and weight of the electrical connection box, as well as the cost.

Although the invention has been described with respect to the specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. An electrical connection box comprising:
a conductor that is an object to be energized;
a current measurement device that measures current flowing through a current measurement target part of the conductor and outputs an output signal based on the measured current; and
a casing in that the conductor and the current measurement device are accommodated, wherein
the current measurement device includes a magnetic sensor that measures the current flowing through the current measurement target part, a substrate that outputs the output signal based on an input signal input from the magnetic sensor, and a magnetic shield member in which the magnetic sensors, the substrate, and the current measurement target part are disposed, the magnetic shield member being configured to shield magnetism between inside and outside of the magnetic shield member, and
the casing includes a sensor accommodation chamber configured to accommodate the magnetic sensor and the substrate, a position of a magnetic detection element of the magnetic sensor with respect to the current measurement target part being arranged at a magnetic detection enabling position in the sensor accommodation chamber, and the magnetic sensor and the substrate being fixed to the sensor accommodation chamber by a fixing member, a shield insertion port into which the magnetic shield member is inserted, and a shield holding chamber formed at positions where relative displacement with respect to the sensor accommodation chamber is impossible, the shield holding chamber being configured to hold the magnetic shield member inserted from the shield insertion port at an accommodation position.

2. The electrical connection box according to claim 1, wherein
the magnetic sensor is a Hall IC having a Hall element as the magnetic detection element.

3. The electrical connection box according to claim 1, wherein
the shield holding chamber is a space into which a held portion of the magnetic shield member is inserted together with insertion of the magnetic shield member into the casing, and the shield holding chamber includes a press-fitting part into which the held portion is press-fitted together with the insertion of the held portions.

4. The electrical connection box according to claim 2, wherein
the shield holding chamber is a space into which a held portion of the magnetic shield member is inserted together with insertion of the magnetic shield member into the casing, and the shield holding chamber includes a press-fitting part into which the held portion is press-fitted together with the insertion of the held portions.

5. The electrical connection box according to claim 1, wherein
the shield holding chamber is a space into which a held portion of the magnetic shield member is inserted together with insertion of the magnetic shield member into the casing,
a holding structure is provided between the held portion and the shield holding chamber to hold the held portion and the shield holding chamber relative to each other, and
the holding structure includes a projecting first locked part provided on one of the held portion and the shield holding chambers, a first locking part provided on the other of the held portion and the shield holding chamber, the first locking part being configured to lock, by bringing the first locked part into contact with the first locking part, movement in a direction opposite to an advance direction of the held portion at the time of the insertion of the held portion into the shield holding chamber, a projecting second locked part provided on one of the held portion and the shield holding chamber, and a second locking part provided on the other of the held portion and the shield holding chamber, the second locking part being configured to lock, by bringing the second locked part into contact with the second locking part, movement in the advance direction of the held portion at the time of insertion of the held portions into the shield holding chamber.

6. The electrical connection box according to claim 2, wherein
the shield holding chamber is a space into which a held portion of the magnetic shield member is inserted together with insertion of the magnetic shield member into the casing,
a holding structure is provided between the held portion and the shield holding chamber to hold the held portion and the shield holding chamber relative to each other, and
the holding structure includes a projecting first locked part provided on one of the held portion and the shield holding chambers, a first locking part provided on the other of the held portion and the shield holding chamber, the first locking part being configured to lock, by bringing the first locked part into contact with the first locking part, movement in a direction opposite to an advance direction of the held portion at the time of the insertion of the held portion into the shield holding chamber, a projecting second locked part provided on one of the held portion and the shield holding chamber, and a second locking part provided on the other of the held portion and the shield holding chamber, the second locking part being configured to lock, by bringing the second locked part into contact with the second locking part, movement in the advance direction of the held portion at the time of insertion of the held portions into the shield holding chamber.

7. The electrical connection box according to claim 1, wherein
the casing is an assembly of a plurality of casing members having at least a first casing member and a second casing member assembled to the first casing member,
the first casing member has the conductor disposed inside and the shield insertion port,
the second casing member has the sensor accommodation chamber and the shield holding chamber, and
the magnetic sensor and the substrate are fixed to the sensor accommodation chamber by the fixing member.

8. The electrical connection box according to claim 2, wherein
the casing is an assembly of a plurality of casing members having at least a first casing member and a second casing member assembled to the first casing member,
the first casing member has the conductor disposed inside and the shield insertion port,
the second casing member has the sensor accommodation chamber and the shield holding chamber, and
the magnetic sensor and the substrate are fixed to the sensor accommodation chamber by the fixing member.

9. The electrical connection box according to claim 3, wherein
the casing is an assembly of a plurality of casing members having at least a first casing member and a second casing member assembled to the first casing member,
the first casing member has the conductor disposed inside and the shield insertion port,
the second casing member has the sensor accommodation chamber and the shield holding chamber, and
the magnetic sensor and the substrate are fixed to the sensor accommodation chamber by the fixing member.

10. The electrical connection box according to claim 4, wherein
the casing is an assembly of a plurality of casing members having at least a first casing member and a second casing member assembled to the first casing member,
the first casing member has the conductor disposed inside and the shield insertion port,
the second casing member has the sensor accommodation chamber and the shield holding chamber, and
the magnetic sensor and the substrate are fixed to the sensor accommodation chamber by the fixing member.

11. The electrical connection box according to claim 5, wherein
the casing is an assembly of a plurality of casing members having at least a first casing member and a second casing member assembled to the first casing member,
the first casing member has the conductor disposed inside and the shield insertion port,
the second casing member has the sensor accommodation chamber and the shield holding chamber, and
the magnetic sensor and the substrate are fixed to the sensor accommodation chamber by the fixing member.

12. The electrical connection box according to claim 6, wherein
the casing is an assembly of a plurality of casing members having at least a first casing member and a second casing member assembled to the first casing member,
the first casing member has the conductor disposed inside and the shield insertion port,
the second casing member has the sensor accommodation chamber and the shield holding chamber, and
the magnetic sensor and the substrate are fixed to the sensor accommodation chamber by the fixing member.
